(19) United States
(12) Patent Application Publication
(10) Pub. No.: US 2014/0056679 A1
(43) Pub. Date: Feb. 27, 2014

(54) WAFER EXCHANGE APPARATUS AND WAFER SUPPORTING HAND

(71) Applicants: Hiroshi Yamabe, Ibara-shi (JP); Hitoshi Obata, Ibara-shi (JP); Katsuhiro Yamazoe, Ibara-shi (JP); Yoshiki Nishijima, Ibara-shi (JP); Kosuke Sakata, Ibara-shi (JP); Shinichi Imai, Ibara-shi (JP); Hiroaki Tsukimoto, Ibara-shi (JP); Keiichi Matsukawa, Fukuyama-shi (JP)

(72) Inventors: Hiroshi Yamabe, Ibara-shi (JP); Hitoshi Obata, Ibara-shi (JP); Katsuhiro Yamazoe, Ibara-shi (JP); Yoshiki Nishijima, Ibara-shi (JP); Kosuke Sakata, Ibara-shi (JP); Shinichi Imai, Ibara-shi (JP); Hiroaki Tsukimoto, Ibara-shi (JP); Keiichi Matsukawa, Fukuyama-shi (JP)

(73) Assignee: TAZMO CO., LTD., Okayama (JP)

(21) Appl. No.: 14/111,085

(22) PCT Filed: Apr. 5, 2012
(86) PCT No.: PCT/JP2012/059332

§ 371 Date: Oct. 10, 2013

(30) Foreign Application Priority Data
Apr. 15, 2011 (JP) 2011-090676

(51) Int. Cl. H01L 21/683

(52) U.S. Cl. CPC H01L 21/6838
USPC 414/749.1; 294/213

(57) ABSTRACT

A wafer exchange apparatus is provided that is compact with excellent accessibility. The wafer exchange apparatus of the present invention includes a first and a second hands (10), (20), a first lifting means (30), a casing (40), a horizontal moving means (50) and a second lifting means (60). The first and the second hands (10), (20) are formed in shapes segmented in the left and right direction with generally line symmetry, and support a wafer (100). The first lifting means (30) moves the second hand (20) upward and downward. The casing (40) has the first lifting means (30) built-in, and supports the first hand (10) at a constant position in height while supporting the second hand (20) movably upward and downward. The horizontal moving means (50) moves the casing (40) horizontally. The second lifting means (60) moves the casing (40) upward and downward.

### TECHNICAL FIELD

The present invention relates to a wafer exchange apparatus that replaces a processed wafer with an unprocessed wafer and to a wafer supporting hand used for such a wafer exchange apparatus.

### BACKGROUND ART

Conventionally, in a wafer processing apparatus performing a certain process to the wafer(s) it contains, it is possible to raise its operating ratio and hence to increase its output by shortening the time needed for wafer exchange in which a processed wafer is taken out and an unprocessed wafer is taken in.

Proposed in Patent Literature 1 is a wafer exchange apparatus that performs the wafer exchange in a series of operations. The wafer exchange apparatus has two hands disposed with a vertical gap left in between, is provided with a lift mechanism that causes the two upper and lower hands to move upward and downward together, and is configured in such a manner that the lift mechanism alone changes absolute heights of the two upper and lower hands.

For example, suppose that on an upper shelf is placed a processed wafer whereas a lower shelf is vacant. Then, the wafer processing apparatus is accessed by the two upper and lower hands with the lower hand supporting an unprocessed wafer, and thus the unprocessed wafer is taken in. And when the lower hand is moved downward while the upper hand is moved upward by operating the lift mechanism so that the gap between the upper and the lower hands is caused to expand, the unprocessed wafer is set onto the lower shelf getting away from the lower hand, and simultaneously the processed wafer having been placed on the upper shelf is supported by the upper hand. In this state, when the upper and the lower hands are moved away from the wafer processing apparatus, the processed wafer is taken out.

Conversely, suppose that on the lower shelf is placed a processed wafer whereas the upper shelf is vacant. Then, the wafer processing apparatus is accessed by the two upper and the lower hands with the upper hand supporting an unprocessed wafer, and thus the unprocessed wafer is taken in. And, when the lower hand is moved upward while the upper hand is moved downward by operating the lift mechanism so that the gap between the upper and the lower hands is caused to contract, the unprocessed wafer is set onto the upper shelf getting away from the upper hand, and simultaneously the processed wafer having been placed on the lower shelf is supported by the lower hand. In this state, when the upper and the lower hands are moved away from the wafer processing apparatus, the processed wafer is taken out.

Citation List

Patent Literature

Patent Literature 1

Japanese Patent Unexamined Publication No. 8-139152 bulletin

### SUMMARY OF INVENTION

2. Technical Problem

In the configuration of the wafer exchange apparatus of Patent Literature 1, since the mechanism that causes the two upper and lower hands to move upward and downward together is complicated, there has been a problem that the apparatus upsizes due to mechanical components put close together. Besides, there has been an inconvenience that the wafer processing apparatus cannot be accessed with a single hand when it is desired to do so due to the two upper and lower hands configuration.

The present invention was contrived to solve the above-mentioned technical problems, and is directed to providing a wafer exchange apparatus and a wafer supporting hand that are compact with excellent accessibility.

2. Solution to Problem

A wafer exchange apparatus of the present invention comprises a first and a second hands, a first lifting means, a casing, a horizontal moving means and a second lifting means. The first and the second hands are formed in shapes segmented in the left and right direction with generally line symmetry, and support a wafer. The first lifting means moves the second hand upward and downward. The casing has the first lifting means built-in, and supports the first hand at a constant position in height while supporting the second hand movably upward and downward. The horizontal moving means moves the casing horizontally. The second lifting means moves the casing upward and downward.

This configuration of the wafer exchange apparatus permits making a relative height of the first and the second hands variable by the first lifting means while making their absolute heights adjustable by the second lifting means. Therefore, mechanical components can be arranged dispersedly. Moreover, when positions in height of the first and the second hands are made even, the first and the second hands become usable as one hand in appearance.

Further, the pair of the wafer supporting hands of the present invention are formed in shapes segmented in the left and right direction with generally line symmetry. This configuration not only permits supporting a wafer with both of the wafer supporting hands united as one hand in appearance by making the heights of the pair of the wafer supporting hands even, but also permits supporting a wafer separately as two hands by making the heights of the pair of the wafer supporting hands different. In other words, one hand in appearance can be used as two hands, and it is possible to constitute in a space saving manner two hands that are used with the heights thereof being separated one another.

The wafer supporting hands may be configured in such a manner that main fingers that take a shape of a fork when joined together with line symmetry are formed at front ends of the pair of the wafer supporting hands, and that supplementary fingers are provided protruding one another alternately to the opposite hands across an axis of the line symmetry at roots of the respective main fingers. With this configuration, the main fingers of the respective hands joined together with line symmetry become a fork-shaped finger when the pair of the wafer supporting hands are to be used as one hand in appearance, whereas the main finger and the supplementary finger of each hand altogether become a fork-shaped finger when the pair of the wafer supporting hands are to be used as two hands. That is to say, it is made possible to support a wafer stably with a fork-shaped finger regardless of whether it is one hand in appearance or two hands to be used.

Further, air-intake openings may be provided at tip portions of the main fingers and the supplementary fingers on wafer support surfaces of the pair of the wafer supporting hands. With this configuration, a wafer can be sucked onto the wafer support surfaces and thus be supported surely by sucking in the air from the air-intake openings with the wafer placed on the wafer support surfaces of the pair of the wafer supporting hands.

### Advantageous Effects of Invention

The present invention makes it possible to provide a wafer exchange apparatus and a wafer supporting hand that are compact with excellent accessibility.

### BRIEF DESCRIPTION OF DRAWINGS

FIG. 1 is a partially cross sectional top view showing a general configuration of a wafer exchange apparatus according to an embodiment of the present invention.

FIGS. 2A through 2C are partially cross sectional side views explaining operations of a first and a second lifting means of the wafer exchange apparatus.

FIG. 3 is top views of a first and a second hands explaining a case where they are used as two hands.

FIG. 4 is a top view of the first and the second hands when joined together explaining a case where they are used as one hand in appearance.

FIGS. 5A through 5D are perspective views explaining an example of wafer exchange operation by the wafer exchange apparatus.

FIGS. 6A through 6D are perspective views explaining another example of wafer exchange operation by the wafer exchange apparatus.

### DESCRIPTION OF EMBODIMENTS

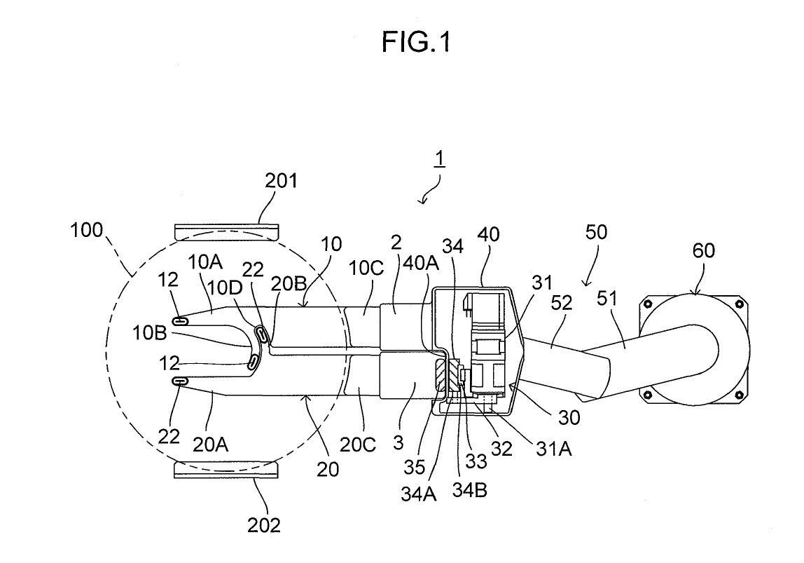

Referring to FIG. 1 through FIG. 3, a general configuration of a wafer exchange apparatus according to an embodiment of the present invention is explained.

As shown in FIG. 1, the wafer exchange apparatus 1 includes a first and a second hands 10, 20, a first lifting means 30, a casing 40, a horizontal moving means 50 and a second lifting means 60.

As shown in FIG. 1, the first and the second hands 10, 20 are formed in shapes segmented in the left and right direction with generally line symmetry.

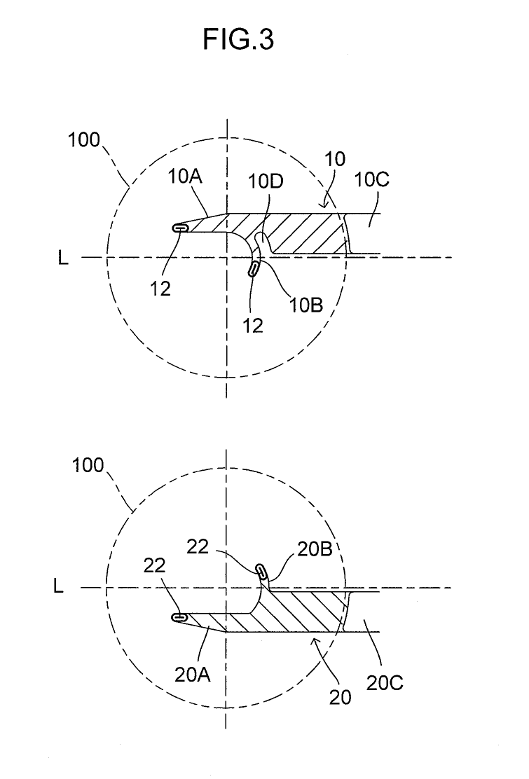

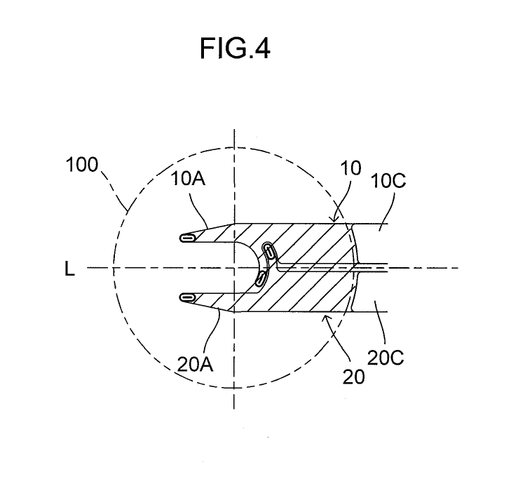

The first and the second hands 10, 20 are formed in a platelike shape, and wafer support surfaces (refer to the slanted line sections in FIG. 3, FIG. 4) that are set in a single surface are formed on each one face's side. Therefore, not only is it made possible to support a wafer 100 with both of the wafer supporting hands 10, 20 united as one hand in appearance by making the heights of the first and the second wafer supporting hands 10, 20 even as shown in slanted lines in the same direction in FIG. 4, but also it is made possible to support a wafer 100 separately as two hands with either of the hands 10, 20 by making the heights of the first and the second wafer supporting hands 10, 20 different as shown in slanted lines in different directions in FIG. 3. In other words, one hand in appearance can be used as two hands, and thus it is possible to constitute in a space saving manner two hands that are used with the heights thereof being separated one another.

Further, as shown in FIG. 3, FIG. 4, main fingers 10A, 20A that take a shape of a fork when joined together with line symmetry are formed at front ends of the first and the second wafer supporting hands 10, 20 respectively. At roots of the respective main fingers 10A, 20A, supplementary fingers 10B, 20B that respectively protrude one another alternately to the opposite hands across an axis L of the line symmetry are provided. In the first hand 10, an inlet-like concave portion 10D is formed adjacent to its supplementary finger 10B, and the concave portion 10D is made in such a manner as to receive the supplementary finger 20B of the second hand 20.

The main fingers 10A, 20A of the respective hands joined together with line symmetry become a fork-shaped finger when the first and the second wafer supporting hands 10, 20 are to be used as one hand in appearance as shown in FIG. 4, whereas the main finger 10A or 20A and the supplementary finger 10B or 20B of each hand altogether respectively become a fork-shaped finger when the first and the second wafer supporting hands 10, 20 are to be used as two hands as shown in FIG. 3. That is to say, it is made possible to support a wafer 100 stably with a fork-shaped finger regardless of whether it is one hand in appearance or two hands to be used.

Further, as shown in FIG. 3, FIG. 4, air-intake openings 12, 22 are provided at tip portions of the main fingers 10A, 20A and the supplementary fingers 10B, 20B respectively on wafer support surfaces of the first and the second wafer supporting hands 10, 20. With this configuration, a wafer 100 can be sucked onto the wafer support surface and thus can be supported surely by sucking in the air from the air-intake openings 12, 22 with the wafer 100 placed on the wafer support surface of the first or the second wafer supporting hand.

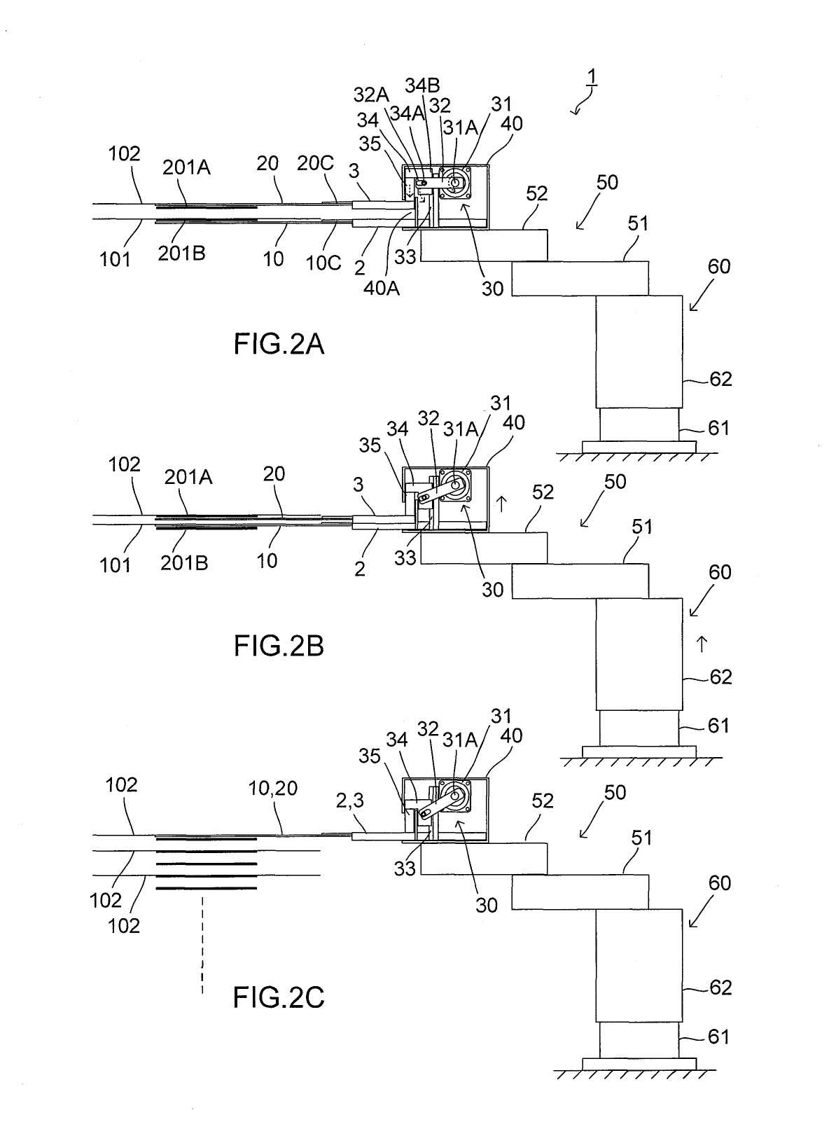

As shown in FIG. 2A, root portions 10C, 20C of the first and the second hands 10, 20 are formed in such a manner as to be higher by one step than the wafer support surfaces. As shown in FIG. 1, edge lines of the root portions 100, 20C are formed to have a circular arc shape so that a circular wafer 100 can be surely supported at an appropriate position on the wafer support surfaces with the root portions 100, 20C employed for positioning.

Platelike holding members 2, 3 hold the first and the second hands 10, 20 by the root portions 100, 20C thereof respectively. The first and the second hands 10, 20 are mounted on the casing 40 using the holding members 2, 3.

The first lifting means 30 moves the second hand 20 upward and downward. As shown in FIG. 1, FIG. 2A, in the embodiment, the first lifting means 30 includes a motor 31, a swinging member 32, a guide 33, and a first and a second slide members 34, 35.

The motor 31 is a driving source that causes a motor shaft 31A to rotate in both directions within a predetermined angular range. As a concrete instance of the motor 31, a stepping motor can be given, for example. The swinging member 32 swings around the motor shaft 31A with the rotation of the motor shaft 31A. A shape of the swinging member 32 is not limited; however, a plate bar-like member as illustrated is used, for example. Onto one end of the swinging member 32, the motor shaft 31A is fixed. At another end of the swinging member 32, the swinging member 32 is penetrated by a slit-like slot 32A extending in a lengthwise direction of the swinging member 32.

The first and the second slide members 34, 35 perform reciprocating linear motions, operating together with swinging motions of the swinging member 32. Shapes of the first and the second slide members 34, 35 are not limited; however, a plate hook-like member as illustrated is used for the first slide member 34, and a platelike member as illustrated is used for the second slide member 35, for example.

As shown in FIG. 2A, a shaft 34A provides a protrusion at one side edge face (a face on this side in FIG. 2A) of a vertically oriented portion of the first slide member 34. The shaft 34A is inserted into the slot 32A of the swinging member 32, and is movable guided by the slot 32A in a lengthwise direction thereof.

As shown in FIG. 1, a rear face of the second slide member 34 extends vertically, and there a guiding groove 34B is formed. A shape of the guiding groove 34B is not limited; however, it can be a rectangular groove as illustrated, for example. The guiding groove 34B engages with a guide 33 installed vertically in the casing 40. A shape of the guide 33 is not limited; however, a plate bar-like member as illustrated is used, for example. The guiding groove 34B and the guide 33 constitute a guiding mechanism. Here, the engaging relationship of the guiding mechanism may be reversed as opposed to the above. That is to say, providing a guiding groove on the guide 33 and forming on the rear face of the first slide member 34 a convex part that engages with the guiding groove of the guide 33 is also acceptable.

As shown in FIG. 2A, an upper edge face of the second slide member 35 is fixed to a front edge portion on a bottom face of a horizontally oriented portion of the first slide member 34. The first slide member 34 and the second slide member 35 thus united looks reversed U-shaped when viewed from a side face. This results in the formation of a gap of which both sides and bottom are left open between a front face of the first slide member 34 and a rear face of the second slide member 35.

As shown in FIG. 1, FIG. 2A, a lower half portion of a front face of the casing 40 is recessed by a dimension corresponding to a width of the holding member 3 holding the second hand 20 and a depth of the second slide member 35. A concave portion 40A thus formed has its top that is left open, thereby providing a space that allows the second slide member 35 to move upward and downward. A back wall of the concave portion 40A is located in the gap. The front face of the first slide member 34 is in contact with a rear face of the back wall of the concave portion 40A. Therefore, the first slide member 34 moves upward and downward being in contact with the back wall of the concave portion 40A and the guide 33, and thus with its forward and backward motion being constrained. This also causes the second slide member 35 to be constrained from moving forward and backward.

The swinging member 32, the guide 33, and the first and the second slide members 34, 35 constitute a cam mechanism. By the cam mechanism, as shown by dotted line arrows in FIG. 2A, a rotary motion of the motor shaft 31A is converted to vertical motions (linear motions) of the first and the second slide members 34, 35. As a result, the holding member 3 also performs a vertical motion, thereby causing the second hand 20 held by the holding member 3 to perform a vertical motion.

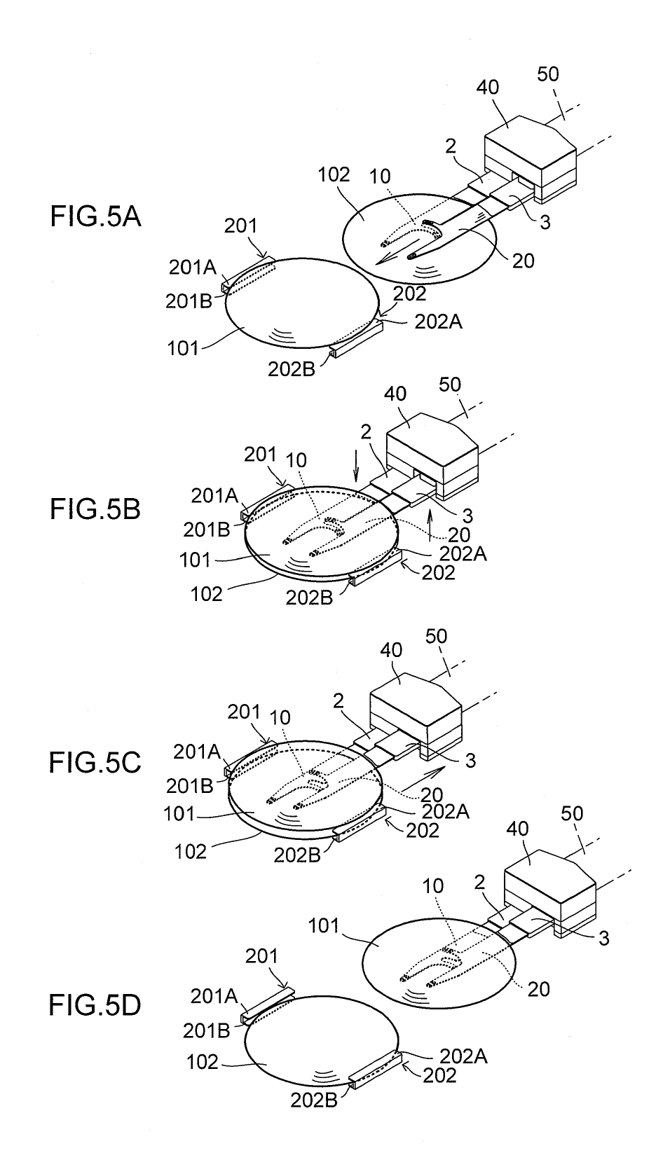

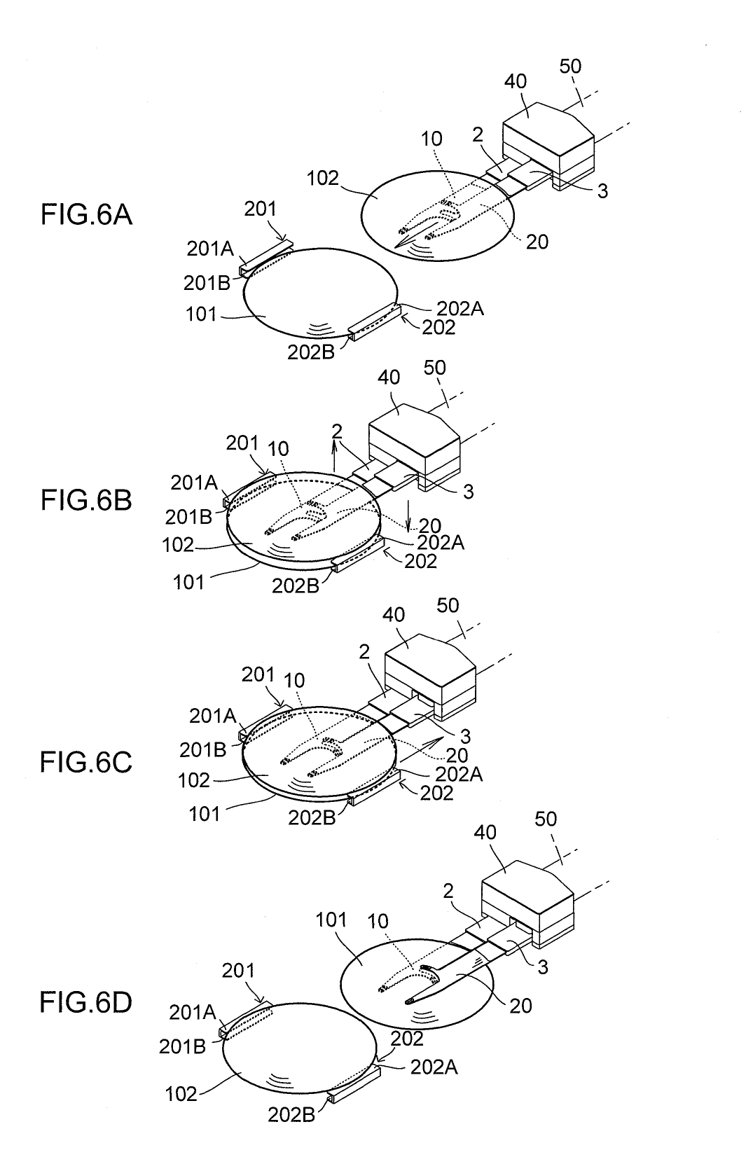

The casing 40 has the first lifting means 30 built-in, and supports the first hand 10 at a constant position in height while supporting the second hand 20 movably upward and downward. The casing 40 takes a boxy shape. A constitution of the casing 40 is not a matter of importance; however, as shown in FIGS. 5A through 5D, FIGS. 6A through 6D, it can be an assembled article consisting of an upper part having a ceiling, a tubular lower part and a base plate, for example.

The holding member 2 holding the first hand 10 is fixed to the base plate of the casing 40. This makes the first hand 10 supported by the casing 40 at a constant position in height (unable to move upward and downward). The holding member 3 holding the second hand 20 is supported by the second slide member 35. This enables the second hand 20 to be supported movably upward and downward by the casing 40.

The horizontal moving means 50 moves the casing 40 horizontally. In the embodiment, the horizontal moving means 50 includes a motor which is not illustrated, articulated robot arms (a first and a second arms 51, 52), and a link mechanism which is not illustrated. At a front edge portion of the second arm 52, the casing 40 is rotatably supported. The motor rotationally drives the first arm 51 of the articulated robot arms. The link mechanism is one that links a rotation of the first arm 51 with rotations of the second arm 52 and the casing 40, and is configured in such a manner that the rotational angles of the second arm 52 and the casing 40 are adjusted properly depending on the rotational angle of the first arm 51. In the embodiment, the link mechanism is configured in such a manner that the casing 40 is moved forward and backward without its direction in appearance being changed by the horizontal moving means 50.

Here, the horizontal moving means is not limited to the one as discussed above in which the casing 40 is moved forward and backward indirectly by the articulated robot arms; instead, it may even be one that directly moves the casing 40 forward and backward with a sliding mechanism, for example.

The second lifting means 60 moves the casing 40 upward and downward. In the embodiment, the second lifting means 60 includes an elevator mechanism which is not illustrated, and a robot main body (a base body 61 and a lifting body 62). The elevator mechanism is not limited; however, it can be constituted with a motor and a crank shaft, for example. The base body 61 is fixed onto a floor surface; and the lifting body 62 is installed in such a manner as to be movable upward and downward freely in relation to the base body 61. Shapes of the base body 61 and the lifting body 62 are not limited; however, cylindrical members as illustrated can be used, for example. The casing 40 is installed to the second lifting means 60 through the above-mentioned horizontal moving means 50.

By the second lifting means 60, as shown by solid line arrows in FIG. 2B, the casing 40 performs a vertical motion with a vertical motion of the lifting body 62. As a result, the holding members 2, 3 also perform vertical motions, and thereby the first and the second hands 10, 20 held by the holding members 2, 3 perform vertical motions.

Operation of the wafer exchange apparatus 1 configured as described above is explained, referring to FIGS. 5A through 5D, FIGS. 6A through 6D. It is postulated that in a wafer processing apparatus for performing a certain process such as heat treatment onto a wafer there are stages 201, 202 installed on side walls or the like of its reception space for wafers. The stages 201 and 202 are provided with shelves 201A, 201B and 202A, 202B in two steps from top to bottom so that a wafer is processed, being set on either step, of the shelves.

For example, as shown in FIG. 5A, suppose that a processed wafer 101 is placed on the upper shelf 201A, 202A and that the lower shelf 201B, 202B is vacant without a wafer. In the wafer exchange apparatus 1 having the above-mentioned configuration, the second hand 20 is located upper by only a smallish distance (in concrete terms, a distance that is smaller than a gap between the upper and the lower shelves) than the first hand 10 by operating the first lifting means 30 (not shown), and then with an unprocessed wafer 102 being supported by the first hand 10, the first and the second hands 10, 20 are caused to access a position between the upper and the lower shelves by operating the horizontal moving means 50. Thereby the unprocessed wafer 102 is taken in to right above the lower shelf 201B, 202B. Then, as shown in FIG. 5B, the casing 40 is moved downward by operating the second lifting means 60 (not shown) while the second hand 20 is moved upward simultaneously by operating the first lifting means 30. This causes, as shown in FIG. 5C, the unprocessed wafer 102 having been supported by the first hand 10 to be placed onto the lower shelf 201B, 202B as the first hand 10 moves downward together with the casing 40, and the processed wafer 101 having been placed on the upper shelf 201A, 202A to be supported by the second hand 20 as the second hand 20 moves upward. In this state, as shown in FIG. 5D, when the first and the second hands 10, 20 are moved away from the shelves by operating the horizontal moving means 50, the processed wafer 101 is taken out of the wafer processing apparatus and the unprocessed wafer 102 is set onto the lower shelf 201B, 202B. In other words, the processed wafer 101 is replaced by the unprocessed wafer 102.

After a processing of a wafer that is set on the lower shelf 201B, 202B is completed, as shown in FIG. 6A, the second hand 20 is located upper by only a slightly bigger distance (in concrete terms, a distance that is bigger than the gap between the upper and the lower shelves) than the first hand 10 by operating the first lifting means 30 (not shown), and then with the unprocessed wafer 102 being supported by the second hand 20, the second hand 20 is caused to access a position above the upper shelf 201A, 202A while the first hand 10 is caused to access a position below the lower shelf 201B, 202B, by operating the horizontal moving means 50. Then, as shown in FIG. 6B, the casing 40 is moved upward by operating the second lifting means 60 (not shown), and simultaneously the second hand 20 is moved downward by operating the first lifting means 30. This causes, as shown in FIG. 6C, the processed wafer 101 having been placed on the lower shelf 201B, 202B is supported by the first hand 10 as the first hand 10 moves upward together with the casing 40, and the unprocessed wafer 102 having been supported by the second hand 20 is placed onto the upper shelf 201A, 202A as the second hand 20 moves downward. In this state, as shown in FIG. 6D, when the first and the second hands 10, 20 are moved away from the shelves by operating the horizontal moving means 50, the processed wafer 101 is taken out of the wafer processing apparatus and the unprocessed wafer 102 is set onto the upper shelf 201A, 202A. In other words, the processed wafer 101 is replaced with the unprocessed wafer 102.

In this manner, take-in of an unprocessed wafer 102 and its setting onto a shelf and take-out of a processed wafer 101 can be performed in a series of operations. Therefore, exchange of the unprocessed wafer 102 and the processed wafer 101 can be performed efficiently.

In the above, the case has been explained in which shelves are provided in two steps; however, in a case where shelves are configured in multistage that is greater than two, and if the number of steps of shelves is an even number, exchange of the unprocessed wafers 102 and the processed wafers 101 can be performed on all the steps by repeating the above-mentioned operations (number of steps)/2 times.

However, if the number of steps of shelves is an odd number, only one step remains halfway in the end when the exchange of the wafers is carried out by two steps at a time as described above. In such a case, in a state where the heights of the first and the second hands 10, 20 are made different, there is a risk that the hands 10, 20 may interfere with a take-out/-in port of the wafer processing apparatus. Accordingly, as shown in FIG. 2C, with the height of the second hand 20 being made to be the same as the height of the first hand 10 by operating the first lifting means 30, the first and the second hands 10, 20 that are formed in segmented shapes are joined together as shown in FIG. 4 so that they behave as one hand in appearance. This state of arrangement of the hands permits the one hand to support a wafer and to access a shelf, thereby making it possible to take in an unprocessed wafer 102, and to take out a processed wafer 101 without causing the hand to interfere with the take-out/-in port of the wafer processing apparatus.

The embodiment permits making a relative height of the first and the second hands 10, 20 variable by the first lifting means 30 while making their absolute heights adjustable by the second lifting means 60. This enables mechanical components to be arranged dispersedly. Also, when positions in height of the first and the second hands 10, 20 are made even, the hands become usable as one hand in appearance. Therefore, it is made possible to provide a wafer exchange apparatus that is compact with excellent accessibility.

The above explanation of the embodiment is nothing more than illustrative in any respect, nor should be thought of as restrictive. Scope of the present invention is indicated by claims rather than the above embodiment. Further, it is intended that all changes that are equivalent to a claim in the sense and realm of the doctrine of equivalence be included within the scope of the present invention.

### REFERENCE SIGNS LIST

1 Wafer exchange apparatus

10 First hand (one of a pair of wafer supporting hands)

20 Second hand (the other of the pair of the wafer supporting hands)

30 First lifting means

40 Casing

50 Horizontal moving means

60 Second lifting means

1. A wafer exchange apparatus comprising:
a first and a second hands that are formed in shapes segmented in the left and right direction with generally line symmetry and support a wafer;
a first lifting means that moves the second hand upward and downward;
a casing that has the first lifting means built-in and supports the first hand at a constant position in height while supporting the second hand movably upward and downward;
a horizontal moving means that moves the casing horizontally; and
a second lifting means that moves the casing upward and downward.

2. A pair of wafer supporting hands that are formed in shapes segmented in the left and right direction with generally line symmetry.

3. The wafer supporting hand as claimed in claim 2, wherein main fingers that take a shape of a fork when joined together with line symmetry are formed at front ends of a pair of the wafer supporting hands; and
supplementary fingers are provided protruding one another alternately to the opposite hands across an axis of the line symmetry at roots of the respective main fingers.

4. The wafer supporting hand as claimed in claim 3, wherein air-intake openings are provided at tip portions of the main fingers and the supplementary fingers on wafer support surfaces of the pair of the wafer supporting hands.
